(19) United States
(12) Patent Application Publication
(10) Pub. No.: US 2025/0258234 A1
(43) Pub. Date: Aug. 14, 2025

(54) SYSTEM FOR PREDICTING THE HEALTH OF BATTERY CELLS

(71) Applicant: Keysight Technologies, Inc., Santa Rosa, CA (US)

(72) Inventors: Manuel Moertelmaier, Wels (AT); Manuel Kasper, Traun (AT)

(21) Appl. No.: 18/975,788

(22) Filed: Dec. 10, 2024

Related U.S. Application Data
(60) Provisional application No. 63/552,782, filed on Feb. 13, 2024.

(51) Int. Cl. G01R 31/367; G01R 31/392; G01R 31/396; G06Q 50/04

(52) U.S. Cl. CPC G01R 31/367; G01R 31/392; G01R 31/396; G06Q 50/04

(57) ABSTRACT

A system and method for predicting a remaining useful life of a cell of a battery is described. The system include a circuit adapted to provide a stimulus signal to the cell; a processor; a tangible, non-transitory computer readable medium that stores instructions, which when executed by the processor, cause the processor to: cycle a plurality of target cells for a test set of cycles; determine a set of features from data from reference cells; determine parameters of a computational model of the remaining useful life of the cell; apply a computational model using the determined set of feature values; and provide a prediction of the remaining useful life of target cells.

### CROSS-REFERENCE TO RELATED APPLICATIONS

This present application claims priority under 35 U.S.C. § 119(e) from U.S. Provisional Application 63/552,782 filed on Feb. 13, 2024. The entire disclosure of U.S. Provisional Application 63/552,782 is specifically incorporated herein by reference.

### BACKGROUND

Battery cell manufacturers need to ensure consistent quality in their product to avoid not only potential safety hazards, but also to improve the reliability of the batteries themselves. In an effort to determine the health and remaining useful life of cells of the battery, battery manufacturers test sample cells from their production line.

One known test method involves fully charging and fully discharging cells in a process commonly referred to as cycling the cells. After a certain number of cycles, typically in the range of a few hundred, the amount of charged cells that are still able to retain is determined, and cells are classified as “pass” and “fail” according to some threshold. While such known cycling methods are useful in predicting the remaining useful life of cells, the current approaches are time-consuming requiring a significant amount of cycling of the cells to determine the remaining useful life. This results in test stations' having a comparatively low throughput and requiring a comparatively great amount of time to carry out the desired testing. The former is costly requiring a rather large capital expenditure, and the latter is a problematic when the faulty cells are in the production line.

Certain techniques to predict the remaining useful life of cells of a battery involve machine learning (ML) in an effort predict the outcome of lengthy cycling experiments. These techniques may involve applying a constant current over the entire test cycle or applying a constant alternating current over the entire test cycle. Among other drawbacks, these known ML methods involve fixed cycling protocols where data sets are also fixed or are based on determining electrochemical properties using expensive test equipment limiting them to short lab experiments, with long cycling studies with many cells seen as too time-consuming.

What is needed, therefore, is a method and system for predicting the remaining useful life of cells of batteries that overcome at least the drawbacks of known methods and systems described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified block diagram of a system for predicting the remaining useful life of cells of a battery in accordance with a representative embodiment.

FIG. 2 is a flow-chart of a method of training and executing a machine learning (ML) model to predict the remaining useful life of a cell of a battery in accordance with a representative embodiment.

FIG. 3A is a graph of discharge current versus time according to a known method of testing cells of a battery.

FIG. 3B is a graph of cell voltage versus time of the known method of FIG. 2A.

FIG. 3C is a graph of stimulus current versus time according to a method of predicting a remaining useful life of a cell of a battery in accordance with a representative embodiment.

FIG. 3D is a graph of cell voltage versus time resulting from the stimulus current of FIG. 2C according to a method of predicting a remaining useful life of a cell of a battery in accordance with a representative embodiment.

FIG. 4 show applied stimulus current and resultant voltage response according to a method of predicting a remaining useful life of a cell of a battery in accordance with a representative embodiment.

### DETAILED DESCRIPTION

In the following detailed description, for the purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third, etc. may be used herein to describe various elements or components, these elements or components should not be limited by these terms. These terms are only used to distinguish one element or component from another element or component. Thus, a first element or component discussed below could be termed a second element or component without departing from the teachings of the inventive concept.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” “comprising,” and/or similar terms specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

By the present teachings a machine learning algorithm is trained to predict the remaining useful life of a cell in a battery. Beneficially, the trained machine learning algorithm (sometimes referred to herein as a remaining useful life (RUL) model) predicts battery degradation using a comparatively small amount of test cycles, and with comparatively small variations of a selected cycling current protocol for optimal data acquisition. As described more fully herein, the cycling data obtained contain features, or data fingerprints, that foster a machine-learning based prediction of battery degradation. Moreover, only small variations in the cycling hardware are required. As opposed to certain known methods and systems for testing cells of batteries, and as alluded to above, the capital expenditure for significant hardware used in systems and methods that test cells using electrical impedance spectroscopy is avoided. In addition, data acquisition may be performed in the context of standard cycling runs, and therefore does not result in extended durations required for testing of cells using certain known methods and systems. Rather, by the present teachings, integration of data acquisition and analysis for predicting the RUL of a cell can be carried out in comparatively short amount of time with minor variations of measurement protocols based on partial analysis results as well as for the carly stopping of measurements as soon as prediction results are conclusive. Accordingly, and among other improvements to the field of battery testing, the presently described representative embodiments provide comparatively less complex testing methods resulting in comparatively fast and accurate predictions of the RUL of a cell of a battery without requiring rather complex and expensive hardware for the testing system.

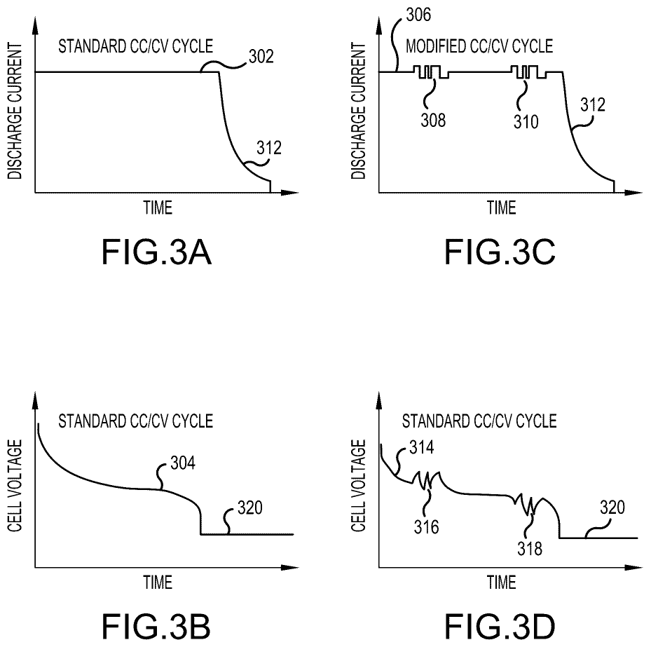

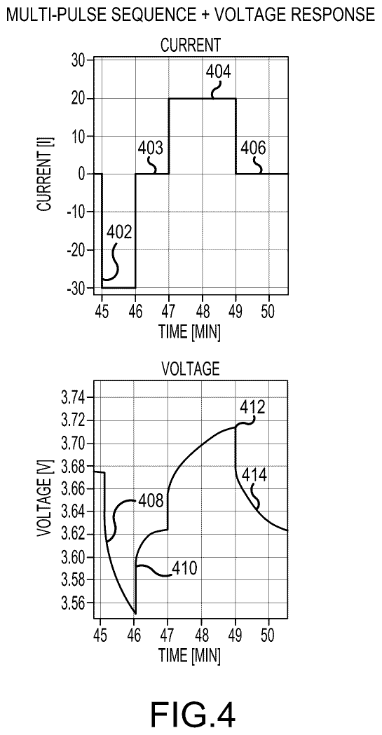

Moreover, and as will be described more fully below, a voltage response of the cell to a small stimulus current that is not constant, or a current response of the cell to a stimulus voltage are used to garner features from a comparatively large number of cells subjected to a comparatively large number of cycles. These features provide the ground truth data (GTD) of the ML algorithm that are used to train the RUL model. As described in connection with FIGS. 3C-4B, stimulus signal is comparatively small in magnitude and duration, and therefore is backwards compatible with many established protocols for cycling cells in battery testing. Applicants have discovered that application of the stimulus signal at approximately 30% and 70% of the of the cycle affords resultant signals that provide useful information on cell parameters, such as complex impedance, which are connected to cell degradation and are therefore predictive of the remaining useful life of the cell. Just by way of illustration, according to a representative embodiment, a stimulus current comprising a series of comparatively small magnitude rectangular pulses are provided during the cycling of the cell. The response comprises a deformed version of the stimulus signal because the voltage response depends on several parameters of the cell.

In accordance with a representative embodiment, a system for predicting a remaining useful life of a cell of a battery is described. The system comprises: a circuit adapted to provide a stimulus signal to the cell; a processor; a tangible, non-transitory computer readable medium that stores instructions, which when executed by the processor, cause the processor to: cycle a plurality of target cells for a test set of cycles; determine a set of features from data from reference cells; determine parameters of a computational model of the remaining useful life of the cell; apply a computational model using the determined set of feature values; and provide a prediction of the remaining useful life of target cells.

In accordance with another representative embodiment, a tangible, non-transitory computer readable medium that stores instructions is disclosed. When executed by a processor, the instructions cause the processor to: provide a stimulus signal to a target cell of a battery; cycle a plurality of target cells for a test set of cycles; determine a set of features from data from reference cells; determine parameters of a computational model of a remaining useful life of the target cell; apply a computational model using the determined set of feature values; and provide a prediction of the remaining useful life of target cells.

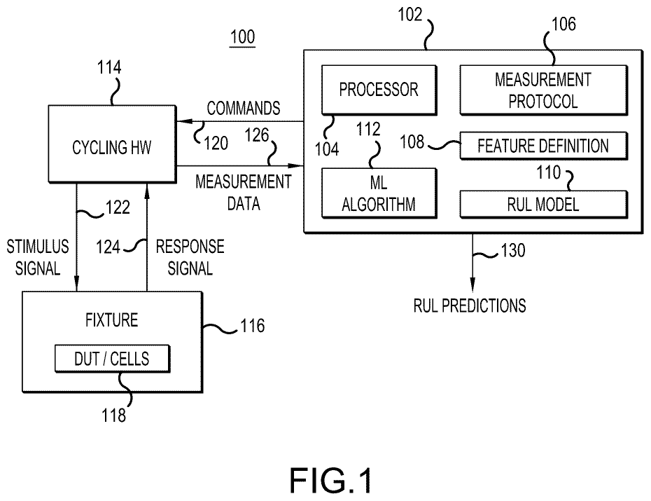

FIG. 1 is a simplified block diagram of a system 100 for predicting the remaining useful life of cells of batteries, according to a representative embodiment.

Referring to FIG. 1, the system 100 comprises a computer 102 for providing a stimulus signal and receiving measurement data 124 from a DUT 118. The computer 102 comprises a processor 104, and a tangible, non-transitory computer readable medium (memory) that stores a trained ML model for predicting the RUL of target cells of a battery.

The memory stores a measurement protocol 106, feature definition 108 and an RUL model 110, which is a trained ML model as described more fully herein.

The memory may also store an ML algorithm 112 that may be used to update the RUL model 110 via training as described more fully herein. “Memory” is an example of computer-readable storage media, and should be interpreted as possibly being multiple memories or databases. The memory may for instance be multiple memories or databases local to the computer 102, and/or distributed amongst multiple computer systems or computing devices.

The system 100 further comprises cycling hardware 114. The cycling hardware 114 provides the stimulus signal 122 to the DUT 118 comprising one or more target cells of a battery and is connected to a test fixture 116. Notably, based on the selected measurement protocol 106, the computer 102 provides commands to effect the measurement protocol. As described more fully below, these commands cause the cycling hardware 114 to provide to the DUT 118 a DC signal and a stimulus signal 122, which has a magnitude and duration that are small compared to the DC signal. Stated somewhat differently, based on commands from the computer 102, the cycling hardware 114 provides a DC signal comprising a time-dependent perturbation signal. In response to the measurement protocol, measurement data 124 are provided to the computer. These measurement data 124 are then provide to the RUL model 110 as test data, and the RUL model 110 predicts the remaining useful life of the target cell(s) of the DUT 118. Notably, the measurement data 124, when the stimulus signal is a current signal, comprises a voltage and a temperature measurement. By contrast, when the stimulus signal is a voltage signal, the measurement data 124 comprises a current and a measurement temperature.

The measurement protocol 106 comprises commands provided to cycling hardware 114 that result in the collection of data from the DUT 118. As will become clearer as the present description continues, the measurement protocol 106 provides commands to charge the target cell and discharge the target cell and record measurement data (e.g., voltage, current and temperature). As such, the measurement protocol 106 comprises a set of instructions stored in the memory, which when executed by the processor 105 provides specific pulse sequence that we superimpose on a DC signal to provide the stimulus signal described more fully below.

As described more fully below, the feature definition 108 comprises linear and nonlinear equations comprising, but not limited to operations such as computing sums, weighted sums, differences, averages, minima, maxima, median values, standard deviations and other quantities that define the features to be used in the ML algorithm 112 to provide the trained RUL model 110 as describe herein. More generally, the feature definition receives the measurement data 124 from the target cell(s) of the DUT 118, and provides floating point numbers used to characterize the information collected from the measurement data. Just by way of illustration, according to a representative embodiment, when the stimulus signal 122 is a current signal, feature values of the feature definition 108 comprise, but are not limited to, a minimum voltage of the plurality of target cells; a voltage of a the plurality of target cells at a specific time; a difference of voltages of the plurality of target cells at different times; a minimum voltage of the plurality of target cells; a mean voltage of the plurality of target cells; a variance of a voltage of the plurality of target cells; a skewness of a voltage of the plurality of target cells; a kurtosis of a voltage of the plurality of target cells; a variance of a voltage of the plurality of target cells; a discharge capacity of the plurality of target cells; a maximum temperature of the plurality of target cells; a minimum temperature of the plurality of target cells; an internal resistance of the plurality of target cells; a resistance and a capacitance of a fit of voltage response to a stimulus signal applied to the plurality of target cells; a projection of a voltage response onto exponential with predetermined time constant of the plurality of target cells; and a complex impedance fit of voltage response to a stimulus signal applied to the plurality of target cells.

The computer 102 is representative of one or more processing devices (e.g., processor 104), and is configured to execute software instructions to perform functions as described in the various embodiments herein. The computer 102 may be implemented by field programmable gate arrays (FPGAs), application specific integrated circuits (ASICs), a general purpose computer (which is transformed to being a specialty purpose computer through the inclusion of the machine-learning algorithms and trained machine learning models of the present teachings), a central processing unit, a computer processor, a microprocessor, a microcontroller, a state machine, programmable logic device, or combinations thereof, using any combination of hardware, software, firmware, hard-wired logic circuits, or combinations thereof. Additionally, any processing unit or processor herein may include multiple processors, parallel processors, or both. Multiple processors may be included in, or coupled to, a single device or multiple devices.

The term “processor” as used herein encompasses an electronic component able to execute a program or machine executable instruction. References to a computing device comprising “a processor” should be interpreted to include more than one processor or processing core, as in a multi-core processor. A processor may also refer to a collection of processors within a single computer system or distributed among multiple computer systems, such as in a cloud-based or other multi-site application. The term computing device should also be interpreted to include a collection or network of computing devices each including a processor or processors. Programs have software instructions performed by one or multiple processors that may be within the same computing device or which may be distributed across multiple computing devices.

The memory comprising the measurement protocol 106, the feature definitions 108, the RUL Model 110, and optionally the ML algorithm 112, may include a main memory and/or a static memory, where such memories may communicate with each other and the controller 120 via one or more buses. The memory 130 stores instructions used to implement some or all aspects of methods and processes described herein. The memory may be implemented by any number, type and combination of random access memory (RAM) and read-only memory (ROM), for example, and may store various types of information, such as software algorithms, which serves as instructions, which when executed by a processor cause the processor to perform various steps and methods according to the present teachings. For example, in accordance with various representative embodiments, the memory that stores instructions, which when executed by the processor, cause the processor to predict the remaining useful life of the cell(s) of the DUT 118 as described more fully below. Furthermore, updates to the RUL model may also be provided to the computer 102 and stored in various components of the memory. For example, in a representative embodiment, updates are provided to the RUL model 110 via a connection to the ML algorithm 112, which may also be updated. Such updates comprise, but are not limited to, modifications of parameters and hyperparameters of the ML algorithm, modifications of the parameters of the RUL model, modifications of the instructions of the ML algorithm, and corrections of bugs. Finally, and as will be apparent to one of ordinary skill in the art having the benefit of the present disclosure, according to a representative embodiment, the ML algorithm 112, or the RUL model 110, or both, may be stored in a memory and executed by a processor that are not part of the computer 102. Just by way of illustration, the RUL model 110 may be stored as executable instructions in a memory, and executed by a server that is remote from system 100. When executed by the processor in the remote server, the instructions cause the processor to carry out the methods of predicting the remaining useful life of a cell(s) of a battery in accordance with various representative embodiments described herein.

The various types of ROM and RAM may include any number, type and combination of computer readable storage media, such as a disk drive, flash memory, an electrically programmable read-only memory (EPROM), an electrically crasable and programmable read only memory (EEPROM), registers, a hard disk, a removable disk, tape, compact disk read only memory (CD-ROM), digital versatile disk (DVD), floppy disk, Blu-ray disk, a universal serial bus (USB) drive, or any other form of storage medium known in the art. The memory 130 is a tangible storage medium for storing data and executable software instructions, and is non-transitory during the time software instructions are stored therein. As used herein, the term “non-transitory” is to be interpreted not as an eternal characteristic of a state, but as a characteristic of a state that will last for a period. The term “non-transitory” specifically disavows fleeting characteristics such as characteristics of a carrier wave or signal or other forms that exist only transitorily in any place at any time. The memory 130 may store software instructions and/or computer readable code that enable performance of various functions. The memory may be secure and/or encrypted, or unsecure and/or unencrypted.

The training sequence of the RUL model 110 is carried out using one of a number of known machine-learning techniques known to those of ordinary skill in the art of AI and mathematical models. In machine-learning, an algorithmic model “learns” how to transform its input data into meaningful output. During the learning sequence, the computational model is shown known examples of inputs and their correct or desired output. These examples are called ground truth, and in accordance with the present teachings comprise the ground truth data (GTD) gathered from a large number of cycles carried out on a large number of cells. During the learning sequence, the ML algorithm 112 adjusts model parameters given the input parameters (feature values), and produces the corresponding meaningful output. The adjustment process is guided by instructions on how to measure the distance between the currently produced output and the desired output. These instructions are called the objective function. As alluded to above, and as described in more detail below, in accordance with various representative embodiments, the RUL model 110 receives feature values from target cell data and outputs a prediction. The prediction may be one of a number of useful predictions to the battery manufacturer, including, but not limited to an estimated lifetime, an estimated remaining useful life, and/or a binary pass/fail indication. The RUL model 110 comprises internal parameters typical for the selected ML algorithm 112 selected to train the RUL model 110.

In accordance with various representative embodiments, and for purposes of illustration and not limitation, the ML algorithm 112 may comprise one of the following known algorithms with parameters selected to realize an acceptable confidence such as via a loss function: a K-nearest neighbor model; an elastic net regression model; a lasso regression model; a neural network model; a support vector machine model; or a random forest model. Moreover, parameters selected for the training of the RUL model 110 to determine the remaining useful life of a cell include, but are not limited to: regression coefficients, and/or an intercept parameter, and/or an alpha parameter for the Lasso regression model; regression coefficients, and/or an intercept parameter, and/or an alpha parameter, and/or an L1 regression parameter for the elastic net regression model; a number of neighbors, and/or weights, and/or a distance metric parameter for the K-nearest neighbor model; weights, and/or biases, and/or temperature parameters for the neural network model; support vectors, and/or weights, and/or a bias parameter, and/or a C parameter for the support vector machine model; and selected features, and/or split points, and/or leaf node values for the random forest model.

As will be appreciated by one of ordinary skill in the art, certain parameters are particularly useful, and some not useful if not counterproductive. As described more fully below, a loss function may be used to determine the useful parameters and ultimately their assigned value. The loss function may be calculated using ground truth data from reference cells used to train the RUL model 110 via the selected ML algorithm 112, and based on the calculated loss function, a determination is made regarding the value assigned to a particular parameter.

The so-called good parameters may be optimized to reduce the loss function to a desired level by training. The optimization is carried out using a known training algorithm.

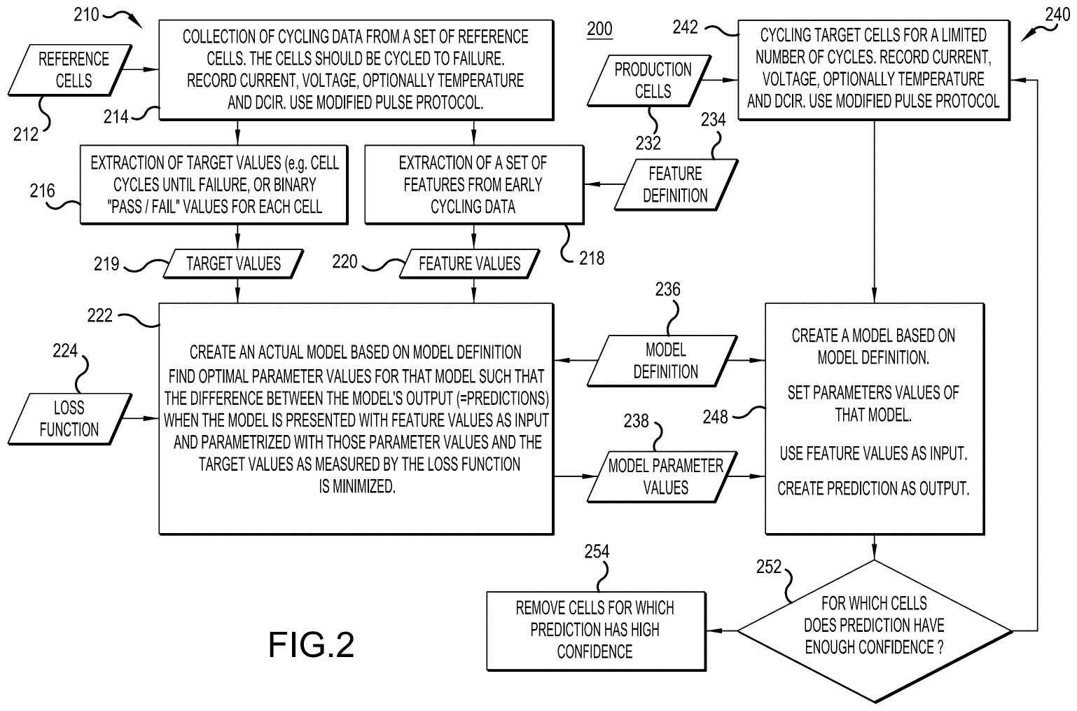

Once parameters are determined for the particular model selected, training of the RUL model 110 is completed to determine the prediction. Execution of the RUL model 110, that is, inference on a trained algorithm, based on feature values from the cell(s) of the DUT 118, thus provides the RUL predictions to the user as shown in FIG. 1. Notably, different test cells may require the determination of different parameters. As such, the training of the RUL model 110, which is described more fully below in connection with representative embodiments of FIG. 2, may be carried out again using new reference data (i.e., ground truth data) for the particular type of cells under test.

FIG. 2 is a flow-chart of a method 200 of training and executing a machine learning (ML) model to predict the remaining useful life of a cell of a battery in accordance with a representative embodiment. Various aspects and details of the method 200 are common to the representative embodiments described in connection with FIG. 1, and those described in connection with FIGS. 3C-4B. These common aspects and details may not be repeated in order to obscure the descriptions of the representative embodiments of FIG. 2.

Notably, the method 200 comprises a method of training 210 an ML algorithm to provide an RUL model according to representative embodiments, and a method of executing 240 the

RUL model according to representative embodiments. As will be appreciated by one of ordinary skill in the art having the benefit of the present disclosure, the method of training 210 the ML model is completed before the method of executing 240 the RUL model, and thus the methods 210, 240 may be provided in separate drawing, and carried out at different times. Moreover, the method of training 210 the ML model is typically done off-site from the battery manufacturing facility, such as by the maker of the testing system, whereas the method of executing 240 the RUL model typically occurs at the battery manufacturing facility. However, in certain representative embodiments, the training may be carried out in an updating sequence at the battery manufacturing facility. As such, and with reference to FIG. 1, the ML algorithm 112 may be a component of the test system deployed at the battery manufacturing facility by application of elements of the method of training 210. Moreover, and as alluded to above, the method of training 210 and the method of executing 240 may be stored as computer executable instructions in memory of the computer 102 which when executed by the processor 104 carries out the methods in accordance with various representative embodiments.

Turning to FIG. 2, method 210 begins at 214 with gathering cycling data from a comparatively large number of reference cells using a modified pulse protocol such as described in connection with FIG. 3C below. For example, 100 reference cells 212 are cycled 600 times between the fully charged state and the fully discharged state illustratively for 100 target variables. In accordance with a representative embodiment, as shown in FIGS. 3C-4B, a stimulus current is applied to the cell repeatedly, and the response voltage and optionally temperature for each cell are recorded. These data become the GTD for training and updating the RUL model as described below.

At 216, target values 219 are extracted from the GTD. These target values are generally determined based on the selected ML algorithm, and may be binary (Pass/Fail) or the number of cycles until cell failure. Based on the number of cycles to failure, the cells may also be graded. As described below, these target values are used to train the selected ML model.

At 218, feature values 220 are extracted from the GTD gathered in 214. Specifically, a feature definition 234 is used to determine the feature values. The feature definition 234 comprises linear and nonlinear equations comprising, but not limited to operations such as computing sums, weighted sums, differences, averages, minima, maxima, median values, standard deviations and other quantities that define the features that are useful in training of the ML algorithm to provide the RUL model, and for execution of the trained RUL model. These feature values are floating point numbers that are used to predict the remaining useful life of a target cell. Just by way of illustration and not limitation, in accordance with various representative embodiments, the feature values can be: a minimum voltage of the plurality of target cells; a minimum voltage of the plurality of target cells; a voltage of a the plurality of target cells at a specific time; a difference of voltages of the plurality of target cells at different times; a mean voltage of the plurality of target cells; a variance of a voltage of the plurality of target cells; a skewness of a voltage of the plurality of target cells; a kurtosis of a voltage of the plurality of target cells; a variance of a voltage of the plurality of target cells; a discharge capacity of the plurality of target cells; a maximum temperature of the plurality of target cells; a minimum temperature of the plurality of target cells; an internal resistance of the plurality of target cells; a resistance and a capacitance of a fit of voltage response to a stimulus signal applied to the plurality of target cells; a projection of a voltage response of the plurality of target cells onto an exponential curve with a predetermined time constant; and; and a complex impedance fit of voltage response to a stimulus signal applied to the plurality of target cells.

At 222, the training of the selected ML algorithm to provide the trained RUL model is carried out. As noted, the model is trained to provide optimal parameter values for the selected model such that the difference between the output of the model (i.e., the prediction) when the model is presented with feature values as inputs and parametrized with the selected parameter values, and the target values, are minimized according to a loss function 224. While the selected loss function depends on the desired output (binary, or relative measure), it is, in essence, using the GTD acquired in 214 to determine a loss function value. The loss function value is then used as a criterion to optimize the parameter values used in the trained model. Specifically, the parameter values are adjusted to minimize the loss function to a satisfactory value. Once the parameter values are determined, the ML algorithm is trained.

Just by way of illustration and not limitation, a loss function, according to a representative embodiment, may be the root mean squared value of the differences in predicted number of cycles to failure and the observed number of cycles to failure of the reference cells. Combined with a RUL model in the form of a multilinear regression predictor without regularization, the ML training algorithm takes on the form of solving an overdetermined system of linear equations, such as by computing a pseudoinverse. Alternatively, the loss function could be chosen to take account of the fact that errors in terms of predicting early failure for a long-lived cell are less critical in practical terms than errors in terms of predicting long life for a short-lived cell. This can be achieved by weighing errors by different factors based on their signs. With such a more complicated loss function, the ML algorithm needs to incorporate a more sophisticated optimization of the RUL model parameter values, such as through gradient descent.

Notably, the procedure of training the ML algorithm in the sequence 214˜222 may be repeated in part or in total to update the model as alluded to above in the description of certain representative embodiments of FIG. 1.

The method 240 for execution of the trained model begins at 242. The method 240 begins with cycling of test cells 232 using a modified pulse protocol such as described in connection with FIG. 3C below. The number of test cycles is generally comparatively small compared to those carried out at 214, illustratively 20 to 40 cycles per test cell. The response data are then recorded. In an illustrative embodiment in which discharge current is used to charge/discharge the test cells, these data may comprise the responsive voltage and optionally the temperature. Moreover, the DC internal resistance (DCIR) may also be measured and recorded.

At 248, the data acquired in 242 are input to the trained RUL model to provide a prediction. Specifically, the model definition 236 and the model parameter values 238 determined at 222 are provided to generate a trained RUL model. Again, for the purposes of illustration and not limitation, the model may be one of the following classes: K-nearest neighbor; elastic net regression; lasso regression; neural networks; support vector machine; or a random forest model.

The parameter values determined at 222 selected for, and provided to the model include, but are not limited to: regression coefficients, and/or an intercept parameter, and/or an alpha parameter for the Lasso regression model; regression coefficients, and/or an intercept parameter, and/or an alpha parameter, and/or an L1 regression parameter for the elastic net regression model; a number of neighbors, and/or weights, and/or a distance metric parameter for the K-nearest neighbor model; weights, and/or biases, and/or temperature parameters for the neural network model; support vectors, and/or weights, and/or a bias parameter, and/or a C parameter for the support vector machine model; and selected features, and/or split points, and/or leaf node values for the random forest model.

The feature values acquired from the target cells in 222 are provided to the trained model, and a prediction of the health of the battery is made using the trained model. The trained model provides a mapping from the feature values to the predictions based on the model parameters. Just by way of illustration and not limitation, according to a representative embodiment, when the RUL model of the life span of a cell based on multilinear regression, the model takes the form of a single linear equation where each input feature is weighted with, i.e. multiplied by, a regression coefficient, and all the result is summed. The resulting number is a prediction of the number of cycles the cell will undergo before failure. This number is different for each cell, as each cell presents different feature values. The model prediction can be computed for each cell separately, or, for efficiency, in the form of one large system of combined linear equations.

By way of illustration, an illustrative Pass/Fail determination can be made by providing as feature values from 222 as input to the trained RUL model. To predict if a cell has an acceptable remaining useful life a certain number of cycles are set as a minimum based on the GTD acquired in 214. So, for example, if the GTD indicates that a cell that survives more than 700 cycles, it is labelled as a so-called “good cell,” and the prediction from the RUL model using the feature values from the target cells in 242 is compared to this minimum. If the prediction from 248 is equal or greater than 700 cycles, the prediction is the cell will pass, and if under 700 cycles, the cell will fail. As such, in accordance with various representative embodiments, the prediction provided by the RUL model in 242 enables identifying target cells that do not meet a predetermined minimum value. Just by way of illustration, according to a representative embodiment, this predetermined minimum value may be a capacity of the cell of at least a certain percentage (e.g., 80%) of the capacity of a cell at a first cycle.

At 252, a confidence value is determined for the predicted value, and the cells that meet this confidence value are designated as good cells Just by way of illustration and not limitation, according to a representative embodiment, in the case of a model based on multilinear regression, the magnitude of the prediction itself can be used as a confidence criterion. If the predicted value is larger, or smaller, than the threshold for separating “good” from “bad” cells, by a predefined criterion value, e.g. 50 cycles, the cell can be confidently assigned to either of those classes. If the predicted value is closer than 50 cycles to the threshold value, the cell is a borderline casc.

At 254, cells are selectively removed based on the confidence value determined in 252 for the predictions of the cells' RUL. Among other benefits, this prevents unnecessary testing on cells in which the RUL can be confidently predicted based on limited experimental data.

As noted above, the methods and systems of the representative embodiments provide efficiencies that improve the overall manufacturing of batteries by predicting which cells are “good” and which cells are not. Even when the prediction is not confident, by eliminating the cells that are confidently “pass” or “fail” from further testing using the trained RUL model, the burden of retesting cells with an RUL that is not confidently determined is significantly reduced. Just for the sake of illustration, suppose after 242 it is determined that 20% of test cells are not determined to be “good” or not with sufficient confidence. This means that only this comparatively small fraction must be cycled at 242 for another set number of cycles (e.g., 30 cycles). For most of the cells, the confidence value is high enough to allow for a comparatively high throughput, reduced downtime of production and improved overall efficiency of manufacturing of batteries to be realized.

Again, for purposes of illustration and not limitation, application of the methods and systems of the representative embodiments may require testing of a comparatively small number of cycles (e.g., 30 cycles) for a comparatively small number of cells is being tested for prediction of their remaining useful life. This be selected, for example, once every 12 hours from the production line. This clearly does not significantly interfere with the production of batteries. By contrast, if every cell had to be tested over a comparatively large number of cycles, the results of the cycling test, and the quality assessment of the produced cells, would be arrived at with a delay of several weeks or months. Again, this provides a clear improvement to the efficiency of battery manufacturing compared to known methods and systems.

FIG. 3A is a graph of discharge current versus time according to a known method of cycling and testing cells of a battery. Notably, a DC discharge current 302 is provided to a cell for a predetermined period of time to effect a charge/discharge cycle.

FIG. 3B is a graph of cell voltage versus time of the known method of FIG. 2A. Notably, a DC voltage 304 of the cell is responsive to the discharge current. As will be appreciated by one of ordinary skill in the art, a constant current is applied to the cell in FIG. 3A, and a change in voltage results. Depending on the directionality of the current, this results in the cell being discharged or charged. At the end of the cycle, a phase 312 can be added during which decreasing current is applied in order to stabilize the cell's voltage 320. This type of cycling may be referred to as constant current-constant voltage (CC-CV) cycling. Among other objectives, this type of cycling enables the cells to be altered between two defined states of charge in a controlled and repeatable manner.

FIG. 3C is a graph of stimulus current versus time according to a method of predicting a remaining useful life of a cell of a battery in accordance with a representative embodiment. Various aspects and details of the representative embodiments described in connection with FIGS. 1-2 may be common to the presently described representative embodiments and may not be repeated in order to avoid obscuring the presently described representative embodiments.

The stimulus current comprises a DC component 306, a first perturbation signal 308 and a second perturbation signal 310. As such, the discharge current of FIG. 3C is a modified CC-CV signal. Notably, in this illustration of the method, the first perturbation signal 308 and the second perturbation signal 310 are disposed at approximately 30% and 70% of the time duration of the DC component 306, in order to obtain features at the cell's states of charge of 30% and 70% respectively. Notably, features obtained at intermediate values tend to be more informative regarding aging processes as those obtained at either 0% or 100% state of charge, that is, between cycles. The exact timing of the perturbation signals can be chosen based on pilot experiments testing the empirical success of prediction algorithms based on the resulting data. As described more fully above, the first perturbation signal 308 and the second perturbation signal 310 comprise rectangular components having a predetermined amplitude and duration. Notably, the first perturbation signal 308 and the second perturbation signal 310 are illustratively the same. In various representative embodiments, such as shown in FIG. 3C, each signal is a comprises a train of several pulses of varying duration chosen to determine the cell's voltage response at varying time scales. This can be regarded as the time-domain equivalent of probing the cell with periodic signals of various frequencies and allows to estimate the cell's complex impedance. Again, the stimulus pattern can be optimized based on empirical success of the prediction algorithm,

FIG. 3D is a graph of cell voltage versus time resulting from the stimulus current of FIG. 3C according to a method of predicting a remaining useful life of a cell of a battery in accordance with a representative embodiment. The resultant voltage versus time shows a first alternating voltage signal 316 resulting from the first perturbation signal 308 and a second alternating voltage signal 318 resulting from the second perturbation signal 310. As the illustrative current perturbation signal comprises a combination of current pulses, the voltage signal contains the exponential response typical of combines RC-circuits. The time constants of the exponentials in each subsection of the response can be extracted and processed as features. The time constants are indicators of electrochemical properties of the cell such as charge-transfer resistance, which in turn are indicators of cell health and degradation.

In accordance with various embodiments of the present disclosure, the methods described herein may be implemented using a hardware computer system that executes software programs. Further, in an exemplary, non-limited embodiment, implementations can include distributed processing, component/object distributed processing, and parallel processing. Virtual computer system processing may implement one or more of the methods or functionalities as described herein, and a processor described herein may be used to support a virtual processing environment.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

FIG. 4 (top) shows a multi-pulse sequence to be superimposed on the constant current during the CC phase in accordance with an embodiment of the present disclosure. FIG. 4 (bottom) shows the corresponding voltage response of the battery cell, in accordance with an embodiment of the present disclosure.

The current sequence consists of two pulses of varying amplitude, polarity, and duration. A first pulse 402 shows a discharge pulse with negative current, followed by a resting period 403. A second pulse 404, of higher amplitude and opposite polarity, represents a charge pulse, which is again succeeded by a resting period 406.

In the voltage-time graph in FIG. 4 (bottom), the immediate voltage response to the termination of each pulse can be observed. The first voltage response 408 to the discharge pulse (first pulse 402) displays an immediate jump in voltage at the end of the pulse, which is due to the internal resistance of the battery cell. The subsequent voltage recovery, denoted by reference numeral 410, demonstrates an exponential rise, characteristic of the RC circuit behavior intrinsic to the battery cell.

Similarly, following the charge, second pulse 404, an immediate voltage drop is observed at 412, again attributable to the internal resistance. The voltage recovery 414 post-charge pulse follows an exponential decay, returning to the resting voltage level. This is the transient response of the voltage as the battery cell recovers from the imposed load conditions.

Both recovery periods after first pulse 402 and second pulse 404 display the exponential voltage recovery typical of the electrochemical and RC circuit characteristics of the battery cell, and allows determination of the cell's impedance at different time scales.

Although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents and shall not be restricted or limited by the foregoing detailed description.

1. A system for predicting a remaining useful life of a cell of a battery, the system comprising:
a circuit adapted to provide a stimulus signal to the cell;
a processor;
a tangible, non-transitory computer readable medium that stores instructions, which when executed by the processor, cause the processor to:
cycle a plurality of target cells for a test set of cycles;
determine a set of features from data from reference cells;
determine parameters of a computational model of the remaining useful life of the cell;
apply a computational model using the determined set of feature values; and
provide a prediction of the remaining useful life of target cells.

2. The system of claim 1, wherein the circuit is one of a voltage supply and the stimulus signal is a voltage signal, or the circuit is a current source, and the stimulus signal is a current signal.

3. The system of claim 1, wherein the feature values comprise one or more of:
a minimum voltage of the plurality of target cells; a minimum voltage of the plurality of target cells; a mean voltage of the plurality of target cells; a voltage of a the plurality of target cells at a specific time; a difference of voltages of the plurality of target cells at different times; a variance of a voltage of the plurality of target cells; a skewness of a voltage of the plurality of target cells; a kurtosis of a voltage of the plurality of target cells; a variance of a voltage of the plurality of target cells; a discharge capacity of the plurality of target cells; a maximum temperature of the plurality of target cells; a minimum temperature of the plurality of target cells; an internal resistance of the plurality of target cells; a resistance and a capacitance of a fit of voltage response to a stimulus signal applied to the plurality of target cells; a projection of a voltage response onto exponential with predetermined time constant of the plurality of target cells; and a complex impedance fit of voltage response to a stimulus signal applied to the plurality of target cells.

4. The system of claim 1, wherein the computational model is a trained model comprising one of: a K-nearest neighbor model; an elastic net regression model; a lasso regression model; a neural network model; a support vector machine model; and a random forest model.

5. The system of claim 4, wherein the computational model comprises the parameters of a computational model of the remaining useful life of the cell, wherein the parameters comprise:
regression coefficients, and/or an intercept parameter, and/or an alpha parameter for the Lasso regression model;
regression coefficients, and/or an intercept parameter, and/or an alpha parameter, and/or an L1 regression parameter for the elastic net regression model;
a number of neighbors, and/or weights, and/or a distance metric parameter for the K-nearest neighbor model;
weights, and/or biases, and/or temperature parameters for the neural network model;
support vectors, and/or weights, and/or a bias parameter, and/or a C parameter for the support vector machine model; and
selected features, and/or split points, and/or leaf node values for the random forest model.

6. The system of claim 1, wherein the parameters are optimized with respect to a loss function.

7. The system of claim 1, wherein the reference cells are cycled to a predetermined cell state, and the processor determines target values based on data from the reference cells.

8. The system of claim 7, wherein the target values comprise ground truth data for the computational model.

9. The system of claim 8, wherein the instructions further cause the processor to adjust the target values to reduce a loss value.

10. The system of claim 1, wherein the prediction comprises identifying target cells that do not meet a predetermined minimum value.

11. The system of claim 10, wherein the predetermined minimum value comprises a capacity of the cell of at least 80% of the capacity of a cell at a first cycle.

12. A tangible, non-transitory computer readable medium that stores instructions, which when executed by a processor, cause the processor to:
provide a stimulus signal to a cell of a battery;
cycle a plurality of target cells for a test set of cycles;
determine a set of features from data from reference cells;
determine parameters of a computational model of a remaining useful life of the cell;
apply a computational model using the determined set of feature values; and
provide a prediction of the remaining useful life of target cells.

13. The computer readable medium of claim 12, wherein the stimulus signal is a voltage signal or a current signal.

14. The computer readable medium of claim 12, wherein the feature values comprise one or more of:
a minimum voltage of the plurality of target cells; a minimum voltage of the plurality of target cells; a mean voltage of the plurality of target cells; a voltage of a the plurality of target cells at a specific time; a difference of voltages of the plurality of target cells at different times; a variance of a voltage of the plurality of target cells; a skewness of a voltage of the plurality of target cells; a kurtosis of a voltage of the plurality of target cells; a variance of a voltage of the plurality of target cells; a discharge capacity of the plurality of target cells; a maximum temperature of the plurality of target cells; a minimum temperature of the plurality of target cells; an internal resistance of the plurality of target cells; a resistance and a capacitance of a fit of voltage response to a stimulus signal applied to the plurality of target cells; a projection of a voltage response onto exponential with predetermined time constant of the plurality of target cells; and a complex impedance fit of voltage response to a stimulus signal applied to the plurality of target cells.

15. The computer readable medium of claim 12, wherein the computational model is a trained model comprising one of: a K-nearest neighbor model; an elastic net regression model; a lasso regression model; a neural network model; a support vector machine model; and a random forest model.

16. The computer readable medium of claim 15, wherein the computational model comprises the parameters of a computational model of the remaining useful life of the cell, wherein the parameters comprise:
regression coefficients, and/or an intercept parameter, and/or an alpha parameter for the Lasso regression model;
regression coefficients, and/or an intercept parameter, and/or an alpha parameter, and/or an L1 regression parameter for the elastic net regression model;
a number of neighbors, and/or weights, and/or a distance metric parameter for the K-nearest neighbor model;
weights, and/or biases, and/or temperature parameters for the neural network model;
support vectors, and/or weights, and/or a bias parameter, and/or a C parameter for the support vector machine model; and
selected features, and/or split points, and/or leaf node values for the random forest model.

17. The computer readable medium of claim 12, wherein the parameters are optimized with respect to a loss function.

18. The computer readable medium of claim 12, wherein the reference cells are cycled to failure, and the processor determines the target values based on data from the reference cells.

19. The computer readable medium of claim 12, wherein the prediction comprises identifying target cells that do not meet a predetermined minimum value.

20. The computer readable medium of claim 19, wherein the predetermined minimum value comprises a capacity of the cell of at least 80% of the capacity of a cell at a first cycle.
